(19) United States
(12) Patent Application Publication
(10) Pub. No.: US 2026/0304062 A1
(43) Pub. Date: Oct. 1, 2026

(54) ACOUSTIC REPRODUCTION SYSTEM

(71) Applicants: KAJIMA CORPORATON, Minato-ku, Tokyo (JP); ADAPTIVE AUDIO LIMITED, Southampton, Hampshire (GB)

(72) Inventors: Tsuguto HOSHINO, Tokyo (JP); Motoki YAIRI, Tokyo (JP); Takashi TAKEUCHI, Winchester (GB); Philip Arthur NELSON, Hampshire (GB)

(21) Appl. No.: 19/479,024

(22) PCT Filed: Apr. 28, 2023
(86) PCT No.: PCT/JP2023/016950

§ 371 Date: Oct. 27, 2025

(51) Int. Cl. H04S 7/00; H03G 3/30; H04R 5/02; H04S 1/00

(52) U.S. Cl. CPC H04S 7/307; H03G 3/3005; H04R 5/02; H04S 1/007; H04S 7/302; H03G 2201/103; H04S 2400/11; H04S 2400/13

(57) ABSTRACT

A sound reproduction system includes a controller configured to cause speakers to reproduce two channels. The controller applies an approximate inverse matrix, which approximates an inverse of a plant matrix representing transfer paths from the speakers to both ears, to a left and right recording signal. The approximate inverse matrix is expressed as a product of a gain correction term that corrects the signal intensity of direct components according to a frequency band, a coefficient correction term that corrects a difference in intensity between the direct components and cross components according to the frequency band, a phase inversion term that inverts the phase of the cross components, and a delay correction term that provides a time difference according to the frequency band of the cross components. The controller has circuits that implement the gain correction term, the coefficient correction term, the phase inversion term, and the delay correction term.

### TECHNICAL FIELD

The present disclosure relates to a sound reproduction system.

### BACKGROUND ART

Patent Literature 1 discloses a sound reproduction system that three-dimensionally reproduces the direction, distance, and spread, and the other features of sound. The system causes a plurality of speakers to reproduce two channels of sound, a left channel and a right channel, based on a left recording signal corresponding to a listener's left ear and a right recording signal corresponding to the listener's right ear. The system has a plurality of left speakers corresponding to the left channel and a plurality of right speakers corresponding to the right channel. The system configures filters for each speaker to cancel crosstalk. Crosstalk is a component of sound that reaches an ear other than the ear targeted for control.

A filter capable of canceling crosstalk is ideally determined by measuring the entire transfer system, represented by a plant matrix, from the speakers to both ears, and calculating the inverse matrix of the measured plant matrix. Hereinafter, the inverse matrix of the plant matrix is referred to as an inverse filter matrix, and a system that controls sound by inversely transforming the transfer system is referred to as an inverse system. When implementing an inverse filter matrix, there are many problems, such as loss of dynamic range, deviation of the listening position, lack of robustness against reflections in the control space, and individual differences in head-related transfer functions.

The system described in Patent Literature 1 solves the above-mentioned problems by using a unique speaker in which the position of the speaker changes continuously according to the frequency of the output sound. However, it is difficult to continuously change the position of the speaker according to the frequency as defined. Therefore, in practice, the speaker positions are discretized, and one of a plurality of frequency bands divided by a predetermined bandwidth is assigned to each speaker as the frequency band that the speaker is responsible for. Such a discretized system achieves independent control of both ears by determining the frequency band of the output sound for each left speaker and each right speaker, and distributing signals of an appropriate frequency bands to an appropriate speakers.

### CITATION LIST

### Patent Literature

[Patent Literature 1] Japanese Unexamined Patent Application Publication (Translation of PCT Application) No. 2004-511118

### SUMMARY OF INVENTION

### Technical Problem

The system described in Patent Literature 1 needs to implement a circuit that performs convolution operations with long filter coefficients in order to strictly configure and control the inverse filter matrix. For this reason, in the system described in Patent Literature 1, there is a risk that the implementation cost will increase. Examples of the implementation cost includes labor costs required for development, the computational load of the operations themselves, the unit price of parts. The present disclosure provides a technique that can reduce the implementation cost related to independent control of both ears.

### Solution to Problem

A sound reproduction system according to one aspect of the present disclosure reproduces sound in a listening space in which a listener is present. The sound reproduction system includes a plurality of speakers and a controller. The plurality of speakers are disposed in the listening space. The controller is configured to cause the plurality of speakers to reproduce two channels of sound including a left channel and a right channel, based on a left recording signal corresponding to a left ear of the listener and a right recording signal corresponding to a right ear of the listener. The plurality of speakers includes a plurality of left speakers corresponding to the left channel and a plurality of right speakers corresponding to the right channel. A discretized frequency bandwidth is preset for each of the plurality of left speakers and for each of the plurality of right speakers such that their respective output frequency bandwidths differ. The controller is configured to apply an approximate inverse matrix that approximates an inverse of a plant matrix representing transfer paths from the plurality of speakers to both ears of the listener to the left recording signal and the right recording signal, thereby causing the plurality of speakers to reproduce sound. The sound output from the plurality of speakers includes direct components, which are sound output from the plurality of left speakers to the listener's left ear and from the plurality of right speakers to the listener's right ear, and cross components, which are sound output from the plurality of left speakers to the listener's right ear and from the plurality of right speakers to the listener's left ear. The approximate inverse matrix is expressed as a product of a gain correction term that corrects the signal intensity of the direct components according to the frequency band, a coefficient correction term that corrects the difference in signal intensity between the direct components and the cross components according to the frequency band, a phase inversion term that inverts the phase of the cross components, and a delay correction term that provides a time difference according to the frequency band of the cross components. The controller includes a plurality of circuits implementing the gain correction term, the coefficient correction term, the phase inversion term, and the delay correction term.

According to this sound reproduction system, the inverse filter matrix, that is, the inverse matrix of the plant matrix representing the transfer paths from the plurality of speakers to both ears, is approximated by an approximate inverse matrix. The approximate inverse matrix is applied to the left recording signal and the right recording signal, whereby the plurality of speakers reproduce sound. The approximate inverse matrix is expressed as a product of the gain correction term, the coefficient correction term, the phase inversion term, and the delay correction term. In other words, the inverse filter matrix, which performs convolution operations with long filter coefficients, is approximately divided into four elements that perform simpler operations such as gain correction, coefficient correction, phase inversion, and delay correction. The functions related to the four elements are implemented by being shared among a plurality of circuits. Therefore, this sound reproduction system can reduce the implementation cost related to independent control of both ears compared to a case where the inverse filter matrix is implemented as is.

In one embodiment, the controller may include an amplification circuit implementing the gain correction term and the coefficient correction term, and a delay circuit implementing the phase inversion term and the delay correction term, and the delay circuit may provide, uniformly within each discretized frequency band, a sum of a time difference at which a phase difference between the direct components and the cross components becomes 180 degrees at a center frequency of the frequency bandwidth, and an arrival time difference between the direct components and the cross components. This allows the sound reproduction system to realize the inverse filter matrix, which performs convolution operations with long filter coefficients, with simpler circuits with lower implementation costs, namely an amplification circuit and a delay circuit. Furthermore, in the delay circuit, a time difference (simple delay) is provided between the sound of the left speaker and the sound of the right speaker so that crosstalk is canceled at a representative frequency (center frequency) from within the frequency band assigned to the speaker. In other words, instead of calculating the inverse filter matrix for each frequency included in the frequency bandwidth assigned to a certain speaker, a time difference at which crosstalk is canceled at the center frequency of the frequency bandwidth of that speaker is calculated, and that time difference is applied to all frequencies included in the frequency band assigned to the speaker. As a result, this sound reproduction system calculates the time difference and the other simple factors for each speaker (for each frequency band), and therefore, although the accuracy of crosstalk cancellation for sound at frequencies deviating from the representative frequency is somewhat reduced compared to the case of calculating the inverse filter matrix for each frequency, the computational cost can be significantly reduced. Examples of the computational cost includes the effort of calculation, the number of tasks.

In one embodiment, the controller may include an amplification circuit implementing the gain correction term and the coefficient correction term, an inversion circuit implementing the phase inversion term, and a delay circuit implementing the delay correction term, wherein the inversion circuit inverts the polarity of the signal, and the delay circuit may provide, uniformly within each discretized frequency band, an arrival time difference between the direct components and the cross components. This allows the sound reproduction system to realize the inverse filter matrix, which performs convolution operations with long filter coefficients, with simpler circuits with lower implementation costs, namely an amplification circuit, an inversion circuit, and a delay circuit. Furthermore, as described above, since the sound reproduction system calculates the time difference and the other simple factors for each speaker (for each frequency band), although the flatness of the frequency characteristics of the sound generated at the ear to be controlled is somewhat reduced for sound at frequencies deviating from the representative frequency compared to the case of calculating the inverse filter matrix for each frequency, the computational cost can be significantly reduced.

In one embodiment, the controller may include a feedback circuit implementing the gain correction term, an amplification circuit implementing the coefficient correction term, and a delay circuit implementing the phase inversion term and the delay correction term, wherein the feedback circuit calculates the gain correction term according to the frequency, and the delay circuit may provide, uniformly within each discretized frequency band, a sum of a time difference at which a phase difference between the direct components and the cross components becomes 180 degrees at a center frequency of the frequency bandwidth, and an arrival time difference between the direct components and the cross components. This sound reproduction system can realize the inverse filter matrix, which performs convolution operations with long filter coefficients, with a simpler circuit with lower implementation costs, namely a feedback circuit, an amplification circuit, and a delay circuit. Furthermore, since the gain correction term having frequency characteristics is set by the feedback circuit, crosstalk can be canceled more accurately compared to the case where the gain correction term is a constant. Furthermore, as described above, since this sound reproduction system calculates the time difference and the other simple factors for each speaker (for each frequency band), although the accuracy of crosstalk cancellation for sound at frequencies deviating from the representative frequency is somewhat reduced compared to the case of calculating the inverse filter matrix for each frequency, the computational cost can be significantly reduced.

In one embodiment, the controller may include a feedback circuit implementing the gain correction term, an amplification circuit implementing the coefficient correction term, an inversion circuit implementing the phase inversion term, and a delay circuit implementing the delay correction term, wherein the feedback circuit calculates the gain correction term according to the frequency, the inversion circuit inverts the polarity of the signal, and the delay circuit may provide, uniformly within each discretized frequency band, an arrival time difference between the direct components and the cross components. This sound reproduction system can realize the inverse filter matrix, which performs convolution operations with long filter coefficients, with simpler circuits with lower implementation costs, namely a feedback circuit, an amplification circuit, an inversion circuit, and a delay circuit. Furthermore, as described above, crosstalk can be canceled more accurately by the feedback circuit. Furthermore, as described above, since this sound reproduction system calculates the time difference and the other simple factors for each speaker (for each frequency band), although the flatness of the frequency characteristics of the sound generated at the ear to be controlled is somewhat reduced for sound at frequencies deviating from the representative frequency compared to the case of calculating the inverse filter matrix for each frequency, the computational cost can be significantly reduced.

In one embodiment, the arrival time difference may be a time difference at which a correlation between an impulse response of the direct components and an impulse response of the cross components is maximized. In this case, the sound reproduction system can set an appropriate arrival time difference based on the impulse response.

In one embodiment, the gain correction term may be a numerical value within a range from 0.1 to 10. When the gain correction term is a constant that does not have frequency characteristics, the sound reproduction system can implement the gain correction term with an amplification circuit.

In one embodiment, the gain correction term may be γ/(1+gᵢ²), where γ is a numerical value within a range from 0.1 to 10, and gᵢ may be a transfer gain ratio, which is a ratio of signal intensities resulting from a path difference between the direct component and the cross component of a speaker in an i-th frequency band. When the gain correction term is a constant based on the path difference between the direct components and the cross components and does not have frequency characteristics, the sound reproduction system can implement the gain correction term with an amplification circuit.

In one embodiment, the transfer gain ratio may be a ratio of a square root of a time-averaged integral of squared values at each time of an impulse response of the direct components to a square root of a time-averaged integral of squared values at each time of an impulse response of the cross components. In this case, the sound reproduction system can set an appropriate transfer gain ratio based on the impulse response.

In one embodiment, the transfer gain ratio may be a ratio of a maximum absolute value among the absolute values at each time of an impulse response of the direct components to a maximum absolute value among the absolute values at each time of an impulse response of the cross components. In this case, the sound reproduction system can set an appropriate transfer gain ratio based on the impulse response.

In one embodiment, the gain correction term and the coefficient correction term may have a transfer gain ratio gᵢ, which is a ratio of signal intensities resulting from a path difference between the direct components and the cross components of a speaker in an i-th frequency band. In this case, the gain correction term and the coefficient correction term can be implemented by a feedback circuit and an amplification circuit, respectively, using the transfer gain ratio gᵢ.

### Advantageous Effects of Invention

According to the present disclosure, a technique is provided that can reduce the implementation cost related to independent control of both ears.

### BRIEF DESCRIPTION OF DRAWINGS

FIG. 1 is a schematic diagram illustrating an example of a sound reproduction system according to an embodiment.

FIG. 2 is a block diagram for explaining binaural synthesis by two-channel speakers.

FIG. 3 is a diagram for explaining the geometric positional relationship between a sound source and a listener.

FIG. 4 is a diagram for explaining the definition of an azimuth span.

FIG. 5 is a diagram for explaining the concept of a pair of monopole sound sources whose azimuth angle changes continuously as a function of frequency.

FIG. 6 is an example of a feedback circuit.

FIG. 7 is a diagram for explaining four examples of implementation methods.

FIG. 8 is a diagram for explaining the evaluation results of the implementation methods shown in FIG. 7.

FIG. 9 is a graph simulating the frequency response at a control point.

FIG. 10 is a result of simulating the sound pressure distribution by a sound reproduction system realized by an approximate inverse matrix.

FIG. 11 is a result of simulating the impulse response of sound arriving at the left ear from a pair of left and right speakers.

FIG. 12 is a calculation result of a cross-correlation function between the impulse response of the direct component and the impulse response of the cross component.

### DESCRIPTION OF EMBODIMENTS

Hereinafter, embodiments of the present disclosure will be described with reference to the drawings. In the following description, the same or corresponding elements are denoted by the same reference numerals, and redundant descriptions will not be repeated. The dimensional ratios in the drawings do not necessarily match those in the description. The terms “upper,” “lower,” “left,” and “right” are based on the illustrated state and are for convenience.

### [Configuration of Sound Reproduction System]

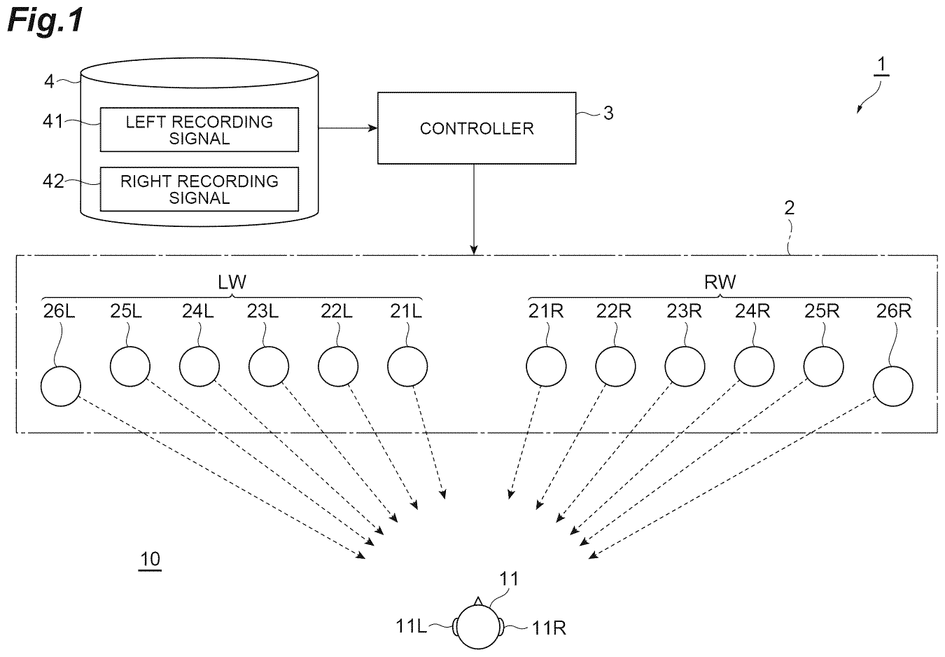

FIG. 1 is a schematic diagram illustrating an example of a sound reproduction system according to an embodiment. A sound reproduction system 1 shown in FIG. 1 reproduces sound in a listening space 10 in which a listener 11 is present. As shown in FIG. 1, the sound reproduction system 1 includes a multi-way speaker unit 2 (an example of a plurality of speakers) disposed in the listening space 10, and a controller 3.

The controller 3 is connected to be able to control the multi-way speaker unit 2. The controller 3 is configured as a computer system including, for example, a processor such as a CPU (Central Processing Unit), memory such as RAM (Random Access Memory) and ROM (Read Only Memory), input/output devices such as a touch panel, a mouse, a keyboard, and a display, and a communication device such as a network card. The controller 3 realizes the functions of the controller 3 described later by the processor operating each hardware component based on a program stored in the memory or the like.

The controller 3 may be configured to be able to refer to a database 4. The database 4 stores sound to be provided to the listener 11. As an example, the database 4 stores a left recording signal 41 corresponding to the left ear 11L of the listener 11 and a right recording signal 42 corresponding to the right ear 11R of the listener 11.

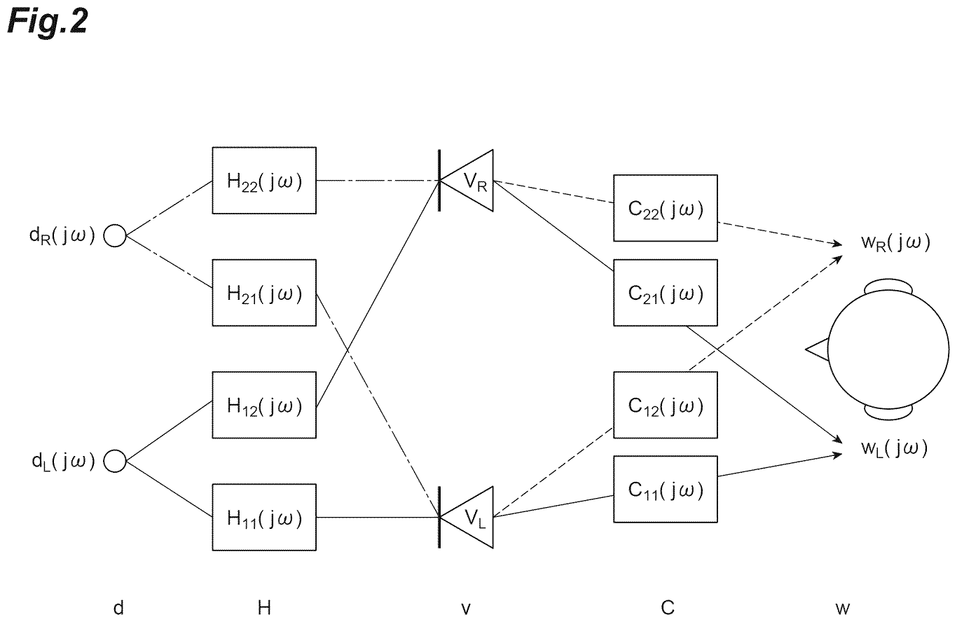

The controller 3 causes the multi-way speaker unit 2 to reproduce two channels of sound based on the left recording signal 41 and the right recording signal 42. The two channels are a left channel Lch and a right channel Rch, details of which will be described later in the description of FIG. 2. The multi-way speaker unit 2 includes a plurality of left speakers LW corresponding to the left channel Lch, and a plurality of right speakers RW corresponding to the right channel Rch. The number of speakers corresponding to each channel is arbitrary.

In the example shown in FIG. 1, the plurality of left speakers LW includes a first left speaker 21L, a second left speaker 22L, a third left speaker 23L, a fourth left speaker 24L, a fifth left speaker 25L, and a sixth left speaker 26L, in order from a position close to the center of the multi-way speaker unit 2 to a position away from it. The plurality of right speakers RW includes a first right speaker 21R, a second right speaker 22R, a third right speaker 23R, a fourth right speaker 24R, a fifth right speaker 25R, and a sixth right speaker 26R, in order from a position close to the center of the multi-way speaker unit 2 to a position away from it.

For each of the plurality of left speakers LW and the plurality of right speakers RW, a frequency bandwidth is preset such that the left and right speakers are configured as pairs, and the sound frequency bandwidth that can be output is different for each pair. For example, it is preset such that the farther from the center position of the multi-way speaker unit 2 (the position facing the median plane of the listener), the narrower the frequency bandwidth of the reproducible sound. As a result, when reproducing high-frequency sound from the multi-way speaker unit 2, sound is output from the left and right speakers close to the center position of the multi-way speaker unit 2. When reproducing low-frequency sound from the multi-way speaker unit 2, sound is output from the left and right speakers far from the center position of the multi-way speaker unit 2.

### [Details of Controller]

The controller 3 applies an approximate inverse matrix, which approximates an inverse matrix of a plant matrix representing transfer paths from the multi-way speaker unit 2 to the left ear 11L and the right ear 11R of the listener 11, to the left recording signal 41 and the right recording signal 42 to cause the multi-way speaker unit 2 to reproduce sound. To explain the approximate inverse matrix realized by the controller 3, a two-channel inverse filter matrix will first be outlined.

### [Two-Channel Inverse Filter Matrix]

FIG. 2 is a block diagram for explaining binaural synthesis by two-channel speakers. As shown in FIG. 2, let the input signal for the right ear be d_{R}(jω) and the input signal for the left ear be d_{L}(jω). ω is the angular frequency.

A two-channel inverse filter matrix H processes two input signals and outputs the filtered signals to two channels, here a sound source V_{R} corresponding to the right channel Rch and a sound source V_{L} corresponding to the left channel Lch. The inverse filter matrix H is, for example, a 2×2 matrix. Let the transfer matrix from the sound sources to the listener's ears be a plant matrix C. The plant matrix C is, for example, a 2×2 matrix. Let the signal received at the right ear be w_{R}(jω) and the signal received at the left ear be w_{L}(jω).

For example, the input signal for the left ear d_{L}(jω) is processed by the matrix elements H₁₁(jω) and H₁₂(jω) of the inverse filter matrix H, and sound is reproduced from the left and right sound sources V_{L} and V_{R}. The sound output from the left sound source V_{L} to the left ear is called a direct component, and the sound output from the right sound source V_{R} to the left ear is called a cross component. The same applies to the right ear; the sound output from the right sound source V_{R} to the right ear is called a direct component, and the sound output from the left sound source V_{L} to the right ear is called a cross component.

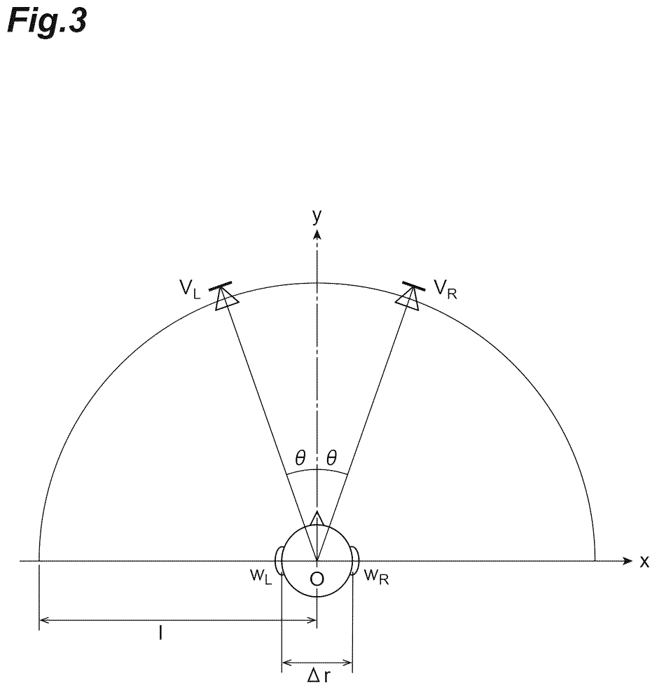

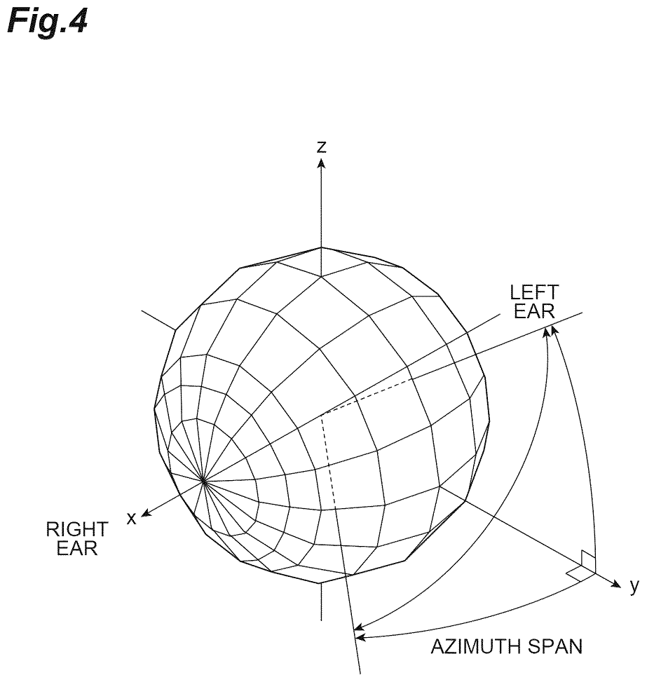

To describe the system shown in FIG. 2 mathematically, the positional relationship between the sound sources and the listener 11 is defined as shown in FIGS. 3 and 4. FIG. 3 is a diagram for explaining the geometric positional relationship between a sound source and a listener, and FIG. 4 is a diagram for explaining the definition of an azimuth span. As shown in FIG. 3, the geometric positional relationship between the sound source and the listener is expressed in a coordinate system where the center point between two ears of the listener 11 as viewed in plan is the origin O of the x-axis. The angle formed by the line connecting the arrangement position of the sound source V_{L} or the sound source V_{R} and the origin O, and the median plane of the listener (y-direction) is defined as the azimuth span θ. As shown in FIG. 4, the azimuth span θ is the difference in azimuth, and is the opening angle between the median plane of the listener 11 and the sound source V_{L} or the sound source V_{R}. Let the equivalent distance between the ears be Δr. The equivalent distance is the actual distance between the two ears corrected to take into account the effect of diffraction around the head. Let the distance from the origin O to the sound source V_{L} or the sound source V_{R} be 1.

In the positional relationship in FIGS. 3 and 4, the direct component p_{d} and the cross component p_{c} of the sound pressure of the sound output from the sound source are described. The direct component p_{d} and the cross component p_{c} are described by the following formulas (1) and (2).

$${p}_{d} = {P}_{0} {g}_{d} {e}^{j ( ω t - {kl}_{d} )} \qquad ( 1 )$$

$${p}_{c} = {P}_{0} {g}_{c} {e}^{j ( ω t - {kl}_{c} )} \qquad ( 2 )$$

Here, P₀ is the loudness of the sound from the sound source, g_{d} is the transfer gain of the direct component p_{d}, l_{d} is the transfer distance of the direct component p_{d}, g_{c} is the transfer gain of the cross component p_{c}, and l_{c} is the transfer distance of the cross component p_{c}.

The transfer matrix C₀ from the sound source to the listener's ear is described by the following matrix (3).

$${C}_{0} = ( \begin{matrix}{p}_{d} & {p}_{c} \\ {p}_{c} & {p}_{d}\end{matrix} ) = {p}_{d} ( \begin{matrix}1 & {ge}^{- jk ( {l}_{c} - {l}_{d} )} \\ {ge}^{- jk ( {l}_{c} - {l}_{d} )} & 1\end{matrix} ) \qquad ( 3 )$$

Here, g is g_{c}/g_{d}, which is the gain ratio of the direct component p_{d} and the cross component p_{c}. In the transfer matrix C₀, the transfer function C normalized by the direct component p_{d} is the following matrix (4).

$$C = \frac{{C}_{0}}{{p}_{d}} = ( \begin{matrix}1 & \text{?} \\ \text{?} & 1\end{matrix} ) \qquad ( 4 )$$

$$\text{?} \text{indicates text missing or illegible when filed}$$

Therefore, the inverse filter matrix H, which is the inverse matrix of the transfer function C, is the following matrix (5).

$$H = {C}^{- 1} = \frac{1}{1 - {g}^{2} \text{?}} ( \begin{matrix}1 & - \text{?} \\ - \text{?} & 1\end{matrix} ) \qquad ( 5 )$$

$$\text{?} \text{indicates text missing or illegible when filed}$$

### [Approximate Inverse Matrix]

The approximate inverse matrix used by the controller 3 is an element-wise partitioned inverse filter matrix H, in which some or all of the c elements are simplified for ease of implementation or improvement of controllability. The inverse filter matrix H shown in matrix (5) can be described by partitioning it into elements as in the following matrix (6).

$$H = \frac{1}{1 - {g}^{2} \text{?}} ( \begin{matrix}1 & g \\ g & 1\end{matrix} ) ⊙ ( \begin{matrix}1 & - 1 \\ - 1 & 1\end{matrix} ) ⊙ ( \begin{matrix}1 & \text{?} \\ \text{?} & 1\end{matrix} ) = α \cdot G ⊙ R ⊙ D \qquad ( 6 )$$

$$α = \frac{1}{1 - {g}^{2} \text{?}} , G = ( \begin{matrix}1 & g \\ g & 1\end{matrix} ) , R = ( \begin{matrix}1 & - 1 \\ - 1 & 1\end{matrix} ) , D = ( \begin{matrix}1 & \text{?} \\ \text{?} & 1\end{matrix} )$$

$$\text{?} \text{indicates text missing or illegible when filed}$$

Here, the symbol enclosing “·” between the matrices is the Hadamard product (element-wise product). α is a gain correction term that corrects the signal intensity of the direct component p_{d} according to the frequency band. G is a coefficient correction term that corrects the difference in signal intensity between the direct component p_{d} and the cross component p_{c} according to the frequency band. R is a phase inversion term that inverts the phase of the cross component p_{c}. D is a delay correction term that provides a time difference according to the frequency band of the cross component p_{c}. Thus, the inverse filter matrix H is expressed as a product of the gain correction term α, the coefficient correction term G, the phase inversion term R, and the delay correction term D.

### [Gain of Inverse Filter Matrix]

Next, the problems and countermeasures when performing binaural control using speakers are outlined. When performing binaural control using speakers, the magnitude of the gain of the inverse filter matrix H (generally the gain correction term α) becomes a problem. If the gain of the inverse filter matrix H is very large, the output of the speakers must be made very large, leading to extreme degradation of sound quality. The transfer gain ratio g between the direct component p_{d} and the cross component p_{c} is often close to 1 in reality, and in this case, the gain correction term α becomes very large when the wave number k and the direction of the sound source satisfy a specific relationship.

Let us consider the conditions under which the control of sound reproduction becomes difficult. Assume that the distance 1 from the origin O to the sound source V_{L} or the sound source V_{R} is sufficiently far compared to the equivalent distance between the ears Δr. In this case, the transfer distances l_{d} and l_{c} can be approximated as in the following formulas (7) and (8).

$${l}_{d} = \sqrt{{( l \cdot sin θ - Δ r / 2 )}^{2} + {l}^{2} \cdot {cos}^{2} θ} ≅ l - \frac{1}{2} Δ r \cdot sin θ \qquad ( 7 )$$

$${l}_{c} = \sqrt{{( l \cdot sin θ + Δ r / 2 )}^{2} + {l}^{2} \cdot {cos}^{2} θ} ≅ l + \frac{1}{2} Δ r \cdot sin θ \qquad ( 8 )$$

The difference in transfer distance between the direct component p_{d} and the cross component p_{c} is Δl=l_{d}−l_{c}. From formulas (7) and (8), the difference in transfer distance Δl is approximated as in the following formula (9).

$$Δ l ≅ Δ r \cdot sin θ \qquad ( 9 )$$

Rewriting the gain correction term α using the transmission gain ratio g~1 and Δl~=−Δr·sin θ gives the following formula (10).

$$\text{?} = \frac{1}{1 - \text{?}} \qquad ( 10 )$$

$$\text{?} \text{indicates text missing or illegible when filed}$$

Here, if we let n=kΔr·sin θ/(π/2), the gain correction term α becomes minimal when n is an odd number, and the control efficiency of sound reproduction becomes good. However, when n is an even number, the gain correction term α diverges, and theoretically, the control of sound reproduction becomes impossible. In reality, when n is an even number, the control efficiency of sound reproduction is significantly degraded.

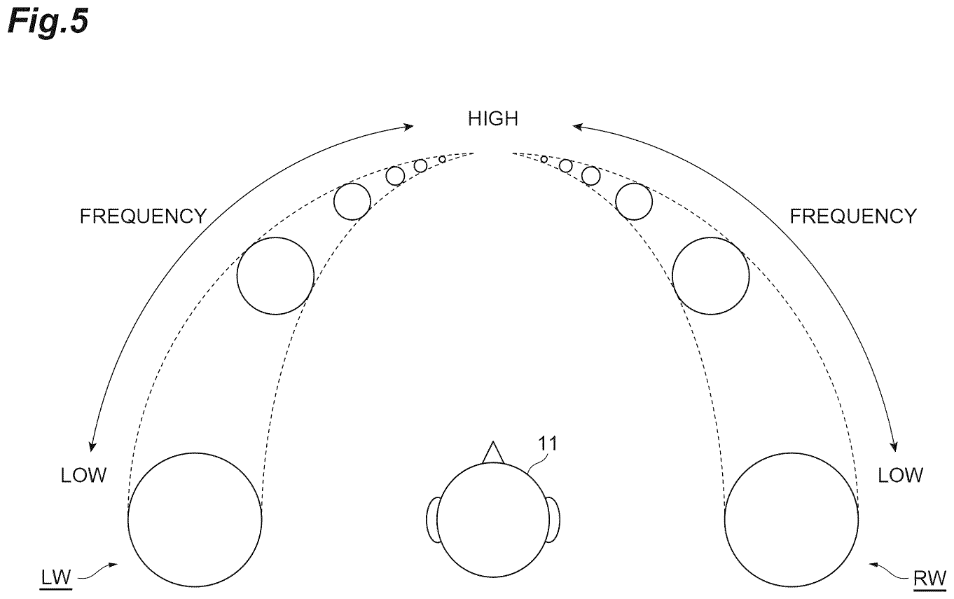

As a countermeasure to efficiently control sound reproduction, a unique speaker can be used in which the position of the speaker changes linearly according to the frequency of the output sound. A pair of conceptual monopole sound sources that satisfy the principle of optimal sound source distribution is shown in FIG. 5. As shown in FIG. 5, it becomes a monopole sound source in which the frequency and the opening angle change continuously while maintaining a constant relationship so as to satisfy n=1 in n=kΔr·sin θ/(π/2). At this time, the plant matrix C and the inverse filter matrix H become very simple matrices as follows.

$$C = ( \begin{matrix}1 & - j \\ - j & 1\end{matrix} ) , H = \frac{1}{2} ( \begin{matrix}1 & j \\ j & 1\end{matrix} )$$

Problems that still remain even when using the principle of sound source distribution described above include the need to implement convolution operations and the need to design an inverse filter for each frequency in the transfer system of each discretized band.

Therefore, the sound reproduction system 1 adopts a conceptual monopole sound source that satisfies the principle of optimal sound source distribution, divides the audible frequency band into a finite number of bands, and reduces the computational cost by having the representative frequency (center frequency) of the divided frequency band represent that frequency band. Then, by configuring an inverse system that does not require convolution operations, a mode is realized in which the implementation cost of the inverse filter is reduced. Hereinafter, a mode extended to a plurality of sound sources will be considered. Suppose that the number of sound sources is 2m, and the audible frequency range is divided into m parts and assigned to the left and right sound sources. In this case, the inverse filter matrix Hᵢ, which is the inverse matrix of the transfer system of the i-th band, can be described as in the following matrix (11).

$${H}_{i} = \frac{1}{1 - {g}_{i}^{2} {e}^{- 2 jk Δ {l}_{i}}} ( \begin{matrix}1 & - {g}_{i} {e}^{- jk Δ {l}_{i}} \\ - {g}_{i} {e}^{- jk Δ {l}_{i}} & 1\end{matrix} ) = {α}_{i} \cdot {G}_{i} ⊙ {R}_{i} ⊙ {D}_{i} \qquad ( 11 )$$

$${α}_{i} = \frac{1}{1 - {g}_{i}^{2} {e}^{- 2 jk Δ {l}_{i}}} , {G}_{i} = ( \begin{matrix}1 & {g}_{i} \\ {g}_{i} & 1\end{matrix} ) , {R}_{i} = ( \begin{matrix}1 & - 1 \\ - 1 & 1\end{matrix} ) , {D}_{i} = ( \begin{matrix}1 & {e}^{- jk Δ {l}_{i}} \\ {e}^{- jk Δ {l}_{i}} & 1\end{matrix} )$$

Here, Δlᵢ is the path difference between the direct component p_{d} and the cross component p_{c} of the sound source of the i-th band, and gᵢ is the gain ratio of the direct component p_{d} and the cross component p_{c} of the sound source of the i-th band.

The controller 3 does not implement the inverse filter matrix Hᵢ as a filter as is, but implements the gain correction term αᵢ, the coefficient correction term Gᵢ, the phase inversion term Rᵢ, and the delay correction term Dᵢ, which are elemental partitions of the inverse filter matrix Hᵢ, with a plurality of circuits. Before explaining the implementation of each element, the time difference Δtᵢ between the direct component p_{d} and the cross component p_{c} of the sound source of the i-th band is defined as follows using the path difference Δlᵢ between the direct component p_{d} and the cross component p_{c} of the sound source of the i-th band and the speed of sound c.

$$Δ {t}_{i} = \frac{Δ {l}_{i}}{c}$$

### [Implementation of Gain Correction Term]

There are two patterns for implementing the gain correction term αᵢ. The first pattern is a method of implementing the gain correction term αᵢ using a feedback circuit, assuming that the gain correction term αᵢ is a term having frequency characteristics. The second pattern is a method of implementing the gain correction term αᵢ with a constant value using an amplification circuit, assuming that the gain correction term αᵢ is a term that does not have frequency characteristics.

First, the first pattern will be described. As shown in matrix (11), the gain correction term αᵢ diverges when the value of the denominator becomes 0, and the control efficiency is significantly degraded. Therefore, the gain correction term αᵢ is approximated as shown in the following formula (12) using a stabilization parameter βᵢ.

$$\text{?} ∼ \text{?} = \frac{1}{1 - \text{?}} \qquad ( 12 )$$

$$\text{?} \text{indicates text missing or illegible when filed}$$

If the input of the approximated gain correction term αᵢ is x and the output is y, the input x and the output y can be described by the following formula (13).

$$y ( t ) = x ( t ) + {β}_{i} {g}_{i}^{2} y ( t - 2 Δ {t}_{i} ) \qquad ( 13 )$$

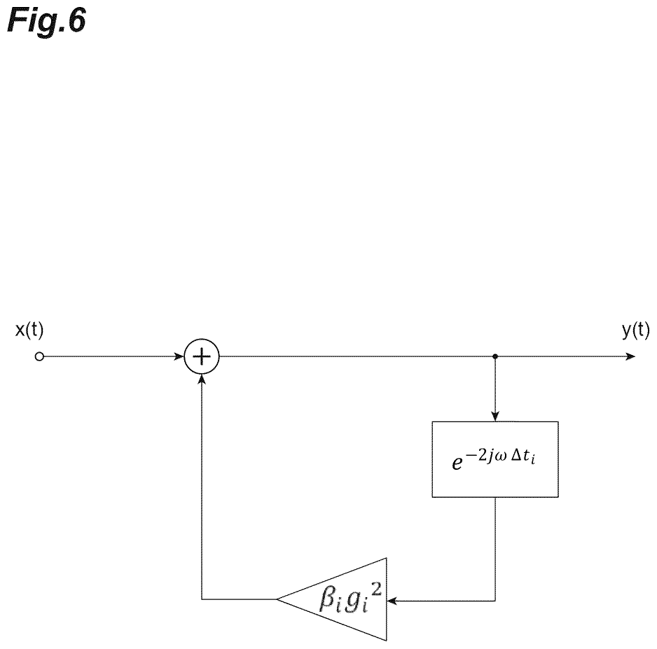

Formula (13) can be implemented with the feedback circuit shown in FIG. 6. The stabilization parameter βᵢ is set to satisfy the following formula (14) after determining the transfer gain ratio gᵢ.

$$0 < {β}_{i} {g}_{i}^{2} < 1 \qquad ( 14 )$$

A method for determining the transfer gain ratio gᵢ will be described later.

Next, the second pattern will be described. In the second pattern, the gain correction term αᵢ is approximated by the following formula (15).

$${α}_{i} ∼ {\tilde{α}}_{i} = \frac{1}{1 + {g}_{i}^{2}} \qquad ( 15 )$$

Formula (15) can be implemented with an amplification circuit. Note that the numerator of formula (15) may be γ, and γ may be a numerical value within a range from 0.1 to 10.

As described above, the gain correction term αᵢ can be implemented with a feedback circuit or an amplification circuit. Note that the gain correction term αᵢ may be a constant regardless of the transfer gain ratio gᵢ. When the gain correction term αᵢ is a constant, for example, a numerical value within a range from 0.1 to 10 may be set as the gain correction term αᵢ.

### [Implementation of Coefficient Correction Term]

The coefficient correction term Gᵢ is implemented as a circuit that bypasses the direct component p_{d} and performs amplification processing only on the cross component p_{c}. That is, the coefficient correction term Gᵢ can be implemented with an amplification circuit of the transfer gain ratio gᵢ.

### [Implementation of Phase Inversion Term]

Similar to the coefficient correction term Gᵢ, the phase inversion term Rᵢ is implemented as a circuit that bypasses the direct component p_{d} and performs processing only on the cross component p_{c}. There are two patterns for implementing the phase inversion term Rᵢ. The first pattern is a pattern of performing inversion processing on the cross component p_{c}, as shown in the following matrix (16).

$${R}_{i} = ( \begin{matrix}1 & - 1 \\ - 1 & 1\end{matrix} ) \qquad ( 16 )$$

Matrix (16) can be implemented with an inversion circuit. The second pattern is a pattern of approximating the phase inversion term Rᵢ with the following matrix (17).

$${R}_{i} ∼ {\tilde{R}}_{i} = ( \begin{matrix}1 & {e}^{- j ω π / {ω}_{i}} \\ {e}^{- j ω n / {ω}_{i}} & 1\end{matrix} ) \qquad ( 17 )$$

Here, ωᵢ=2πfᵢ, and fᵢ is the center frequency of the i-th frequency band. Matrix (17) can be implemented with a simple delay circuit with a delay amount of π/ωᵢ. Note that by replacing the phase inversion processing with simple delay processing, it is also possible to integrate the phase inversion term Rᵢ and the delay correction term Dᵢ described later and implement them with a single simple delay circuit.

### [Implementation of Delay Correction Term]

Similar to the coefficient correction term Gᵢ, the delay correction term Dᵢ is implemented as a circuit that bypasses the direct component p_{d} and adds simple delay processing only to the cross component p_{c}. That is, the delay correction term Dᵢ can be implemented with a simple delay circuit.

### [Summary of Implementation Methods]

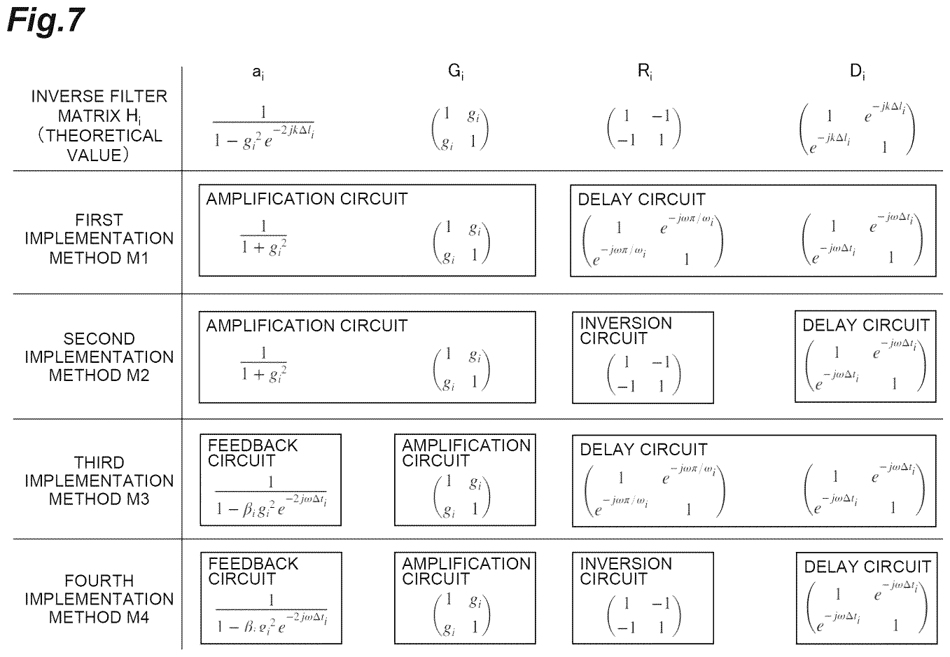

The implementation methods for the gain correction term αᵢ, the coefficient correction term Gᵢ, the phase inversion term Rᵢ, and the delay correction term Dᵢ described above are combinations of the possible patterns for each element. FIG. 7 is a diagram for explaining four examples of implementation methods. As shown in FIG. 7, the implementation methods for the controller 3 include a first implementation method M1, a second implementation method M2, a third implementation method M3, and a fourth implementation method M4.

The first implementation method M1 uses an approximate inverse matrix in which the inverse filter matrix Hᵢ is approximated as in matrix (18). In the following, as a notation method, elements assigned to different circuits are explicitly shown separated by an operator. For example, “ab” indicates that ab is realized by one circuit, and “a·b” indicates that ab is realized by two circuits.

$${H}_{i} ∼ {\tilde{H}}_{i , M 1} = \frac{1}{1 - {g}_{i}^{2}} ( \begin{matrix}1 & {g}_{i} \\ {g}_{i} & 1\end{matrix} ) ⊙ ( \begin{matrix}1 & {e}^{- j ω ( Δ {t}_{i} + π / {ω}_{i} )} \\ {e}^{- j ω ( Δ {t}_{i} + π / {ω}_{i} )} & 1\end{matrix} ) \qquad ( 18 )$$

As shown in matrix (18) and FIG. 7, the gain correction term αᵢ and the coefficient correction term Gᵢ are implemented by an amplification circuit, and the phase inversion term Rᵢ and the delay correction term Dᵢ are implemented by a delay circuit. Each coefficient matrix is implemented in the order of the amplification circuit and the delay circuit.

In order to realize independent control of both ears in two channels, in the processing related to one side's recording signal, after correcting the arrival time difference between the direct component and the cross component, the signs between the signal related to the left channel and the signal related to the right channel need to be reversed. In the sound reproduction system 1, the above-mentioned condition is approximately realized by providing a delay time Δtᵢ between the signals and inverting the polarity of one of the signals. In the first implementation method M1, not only the delay time Δtᵢ but also the polarity inversion is implemented by a delay circuit. The polarity inversion can be realized by setting a time difference (delay amount π/ωᵢ) at which the phase difference between the direct component p_{d} and the cross component p_{c} becomes 180 degrees. That is, the delay circuit sets the final time difference as the sum of the time difference at which the arrival time difference between the direct component p_{d} and the cross component p_{c} becomes 180 degrees, and the arrival time difference (delay time Δtᵢ) between the direct component p_{d} and the cross component p_{c}. Then, in the delay circuit, the above-mentioned final time difference is provided at the center frequency of the frequency bandwidth assigned to the speaker, and that time difference is applied to all frequencies included in the frequency band assigned to the speaker. In this way, the sound reproduction system 1 can significantly reduce the computational cost by providing a time difference uniformly within each discretized frequency band.

The second implementation method M2 uses an approximate inverse matrix in which the inverse filter matrix Hᵢ is approximated as in matrix (19).

$${H}_{i} ∼ {\tilde{H}}_{i , M 2} = \frac{1}{1 - {g}_{i}^{2}} ( \begin{matrix}1 & {g}_{i} \\ {g}_{i} & 1\end{matrix} ) ⊙ ( \begin{matrix}1 & - 1 \\ - 1 & 1\end{matrix} ) ⊙ ( \begin{matrix}1 & {e}^{- j ω Δ {t}_{i}} \\ {e}^{- j ω Δ {t}_{i}} & 1\end{matrix} ) \qquad ( 19 )$$

As shown in matrix (19) and FIG. 7, the gain correction term αᵢ and the coefficient correction term Gᵢ are implemented by an amplification circuit, the phase inversion term Rᵢ is implemented by an inversion circuit, and the delay correction term Dᵢ is implemented by a delay circuit. Each coefficient matrix is implemented in the order of the amplification circuit, the inversion circuit, and the delay circuit. Compared to the first implementation method M1, the circuit that implements the phase inversion term Rᵢ is different. In the second implementation method M2, the delay circuit provides the arrival time difference (delay time Δtᵢ) between the direct component p_{d} and the cross component p_{c} uniformly within each frequency band. This allows the sound reproduction system 1 to significantly reduce the computational cost.

The third implementation method M3 uses an approximate inverse matrix in which the inverse filter matrix Hᵢ is approximated as in matrix (20).

$${H}_{i} ∼ {\tilde{H}}_{i , M 3} = \frac{1}{1 - {β}_{i} {g}_{i}^{2} {e}^{- 2 j ω Δ {t}_{i}}} ⊙ ( \begin{matrix}1 & {g}_{i} \\ {g}_{i} & 1\end{matrix} ) ⊙ ( \begin{matrix}1 & {e}^{- j ω ( Δ {t}_{i} + π / {ω}_{i} )} \\ {e}^{- j ω ( Δ {t}_{i} + π / {ω}_{i} )} & 1\end{matrix} ) \qquad ( 20 )$$

As shown in matrix (20) and FIG. 7, the gain correction term αᵢ is implemented by a feedback circuit, the coefficient correction term Gᵢ is implemented by an amplification circuit, and the phase inversion term Rᵢ and the delay correction term Dᵢ are implemented by a delay circuit. Each coefficient scalar and matrix is implemented in the order of the feedback circuit, the amplification circuit, and the delay circuit. Compared to the first implementation method M1, the circuit that implements the gain correction term αᵢ is different. In the third implementation method M3, the feedback circuit calculates the gain correction term αᵢ according to the frequency. This allows the sound reproduction system 1 to cancel crosstalk more accurately compared to the case where the gain correction term αᵢ is a constant.

The fourth implementation method M4 uses an approximate inverse matrix in which the inverse filter matrix Hᵢ is approximated as in matrix (21).

$${H}_{i} ∼ {\tilde{H}}_{i , M 4} = \frac{1}{1 - {β}_{i} {g}_{i}^{2} {e}^{- 2 j ω Δ {t}_{i}}} ⊙ ( \begin{matrix}1 & - 1 \\ - 1 & 1\end{matrix} ) ⊙ ( \begin{matrix}1 & {g}_{i} \\ {g}_{i} & 1\end{matrix} ) ⊙ ( \begin{matrix}1 & {e}^{- j ω Δ {t}_{i}} \\ {e}^{- j ω Δ {t}_{i}} & 1\end{matrix} ) \qquad ( 21 )$$

As shown in matrix (21) and FIG. 7, the gain correction term αᵢ is implemented by a feedback circuit, the coefficient correction term Gᵢ is implemented by an amplification circuit, the phase inversion term Rᵢ is implemented by an inversion circuit, and the delay correction term Dᵢ is implemented by a delay circuit. Each coefficient scalar and matrix is implemented in the order of the feedback circuit, the inversion circuit, the amplification circuit, and the delay circuit. Compared to the first implementation method M1, the circuits that implement the gain correction term αᵢ and the phase inversion term Rᵢ are different. In the fourth implementation method M4, the delay circuit provides the arrival time difference (delay time Δtᵢ) between the direct component p_{d} and the cross component p_{c} uniformly within each frequency band. The feedback circuit calculates the gain correction term αᵢ according to the frequency. This allows the sound reproduction system 1 to cancel crosstalk more accurately compared to the case where the gain correction term αᵢ is a constant.

### [Simplification of Inverse System Design Method]

In a related art system that adopts the principle of optimal sound source distribution, it is necessary to design the inverse filter matrix for each frequency. In contrast, the sound reproduction system 1 only needs to design the delay time Δtᵢ and the transfer gain ratio gᵢ between the direct component p_{d} and the cross component p_{c} for each discretized frequency band. That is, when using 2m speakers, two parameters are set for a pair of left and right speakers, so a total of 2m parameters need to be set. In this way, the sound reproduction system 1 can also simplify the design method of the inverse system.

### [Setting of Arrival Time Difference (Delay Time) Between Direct Component and Cross Component]

Since the difference in transfer distance Δl is approximated by the above-mentioned formula (9), the delay time Δtᵢ can be set by the following formula (22).

$$Δ {t}_{i} ≅ ( Δ r \cdot sin θ ) / c \qquad ( 22 )$$

In reality, it is necessary to consider the time to bypass the head and pinna, and the ohter obstacles around the head. For this reason, the time difference at which the correlation between the impulse response of the direct component p_{d} and the impulse response of the cross component p_{c} is maximized is adopted. The time difference at which the correlation of the impulse responses is maximized is the time difference at which the waveforms of the mutual impulse responses overlap the most when moved along the time axis. The time difference may be obtained by moving the waveforms, or may be calculated using the cross-correlation function shown in the following formula (23).

$$Δ {t}_{i} = {arg}_{τ} max {\int }_{- ∞}^{∞} {h}_{d , i} ( t ) \cdot {h}_{c , i} ( t + τ ) dt \qquad ( 23 )$$

Here, h_{d,i} is the impulse response of the i-th direct component p_{d,i}, and h_{c,i} is the impulse response of the i-th cross component p_{c,i}. Note that zero-padding is performed for the non-causal component t<0. Also, argₓmaxf(x) is an operator that returns x when the function f(x) gives the maximum value.

### [Setting of Transfer Gain Ratio Between Direct Component and Cross Component]

Regarding the setting of the transfer gain ratio gᵢ, it is generally sufficient to consider only the distance attenuation of the point source, and the transfer gain g_{d,i} of the direct component p_{d} and the transfer gain g_{c,i} of the cross component p_{c} are shown by the following formula (24).

$${g}_{d , i} = \frac{1}{\sqrt{4 π {l}_{d , i}^{2}}} , {g}_{c , i} = \frac{1}{\sqrt{4 π {l}_{c , i}^{2}}} \qquad ( 24 )$$

Since the transfer distances l_{d} and l_{c} are approximated by formulas (7) and (8), the transfer gain ratio gᵢ can be approximated by the following formula (25).

$${g}_{i} = \frac{{g}_{c , i}}{{g}_{d , i}} = \frac{{i}_{d , i}}{{i}_{c , i}} ≅ \frac{1 - ( Δ r sin {θ}_{i} ) / 2}{1 + ( Δ r sin {θ}_{i} ) / 2} \qquad ( 25 )$$

Furthermore, if the transfer distance l is much larger than the equivalent distance between the ears Δr, the transfer gain ratio can be set to gᵢ≈1 as a simpler condition.

Similar to the delay time Δtᵢ, the transfer gain ratio gᵢ realistically needs to consider the distance of a detour around the head, the pinna, and the other obstacles around the head. There are various methods for evaluating the transfer gain ratio gᵢ that takes into account the bypassing distance, but here, a method based on the effective value and a method based on the maximum energy value are exemplified.

First, a method for evaluating the transfer gain ratio gᵢ by the effective value will be described. This method involves taking the square root of the value obtained by dividing the integral value of the square of the impulse response that takes the head into account by the integration time length, and setting it as the transfer gain of each of the direct component and the cross component. For example, the transfer gain g_{d,i} of the direct component p_{d,i} and the transfer gain g_{c,i} of the cross component p_{c,i} can be as in the following formula (26).

$${g}_{d , i} = \sqrt{\frac{1}{T} {\int }_{0}^{T} {h}_{d , i}^{2} ( t ) dt} , {g}_{c , i} = \sqrt{\frac{1}{T} {\int }_{0}^{T} {h}_{c , i}^{2} ( t ) dt} \qquad ( 26 )$$

Here, T is the time until the impulse response is sufficiently attenuated. The transfer gain ratio gᵢ is the ratio of the square root of the value obtained by time-averaging the squared value at each time of the impulse response of the direct component p_{d,i} shown in formula (26), to the square root of the value obtained by time-averaging the squared value at each time of the impulse response of the cross component p_{c,i}.

Next, a method for evaluating the transfer gain ratio gᵢ by the maximum energy value will be described. It can be said that there is a high possibility of correlation if they are maximum energy values. The transfer gain g_{d,i} of the direct component p_{d,i} with the maximum energy and the transfer gain g_{c,i} of the cross component p_{c,i} can be as in the following formula (27).

$${g}_{d , i} = max \vert {h}_{d , i} ( t ) \vert , {g}_{c , i} = max \vert {h}_{c , i} ( t ) \vert \qquad ( 27 )$$

The transfer gain ratio gᵢ can be the ratio of the maximum value among the absolute values at each time of the impulse response of the direct component p_{d,i} shown in formula (27), to the maximum value among the absolute values at each time of the impulse response of the cross component p_{c,i}.

### [Evaluation of Each Implementation Method]

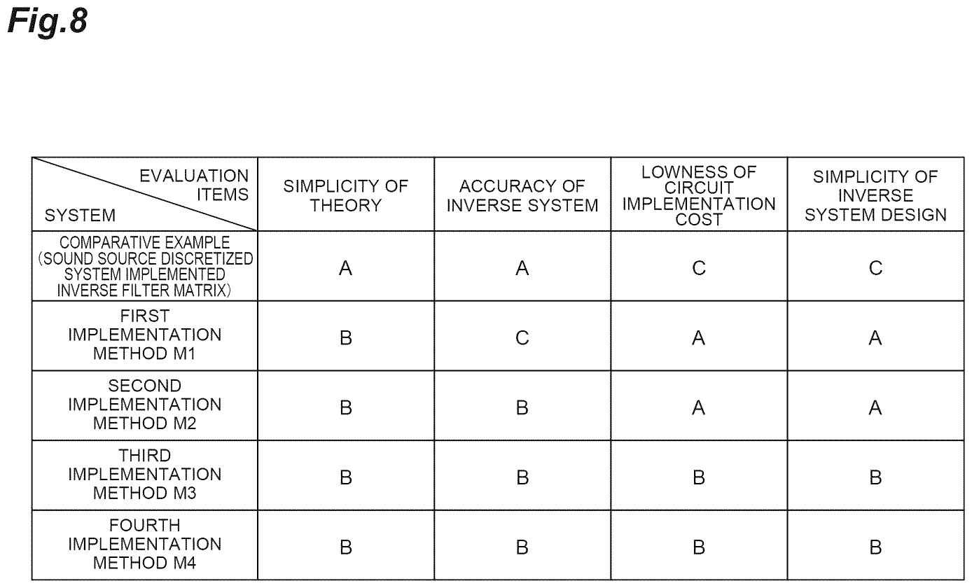

Each of the implementation methods described above was evaluated together with a comparative example. The results are shown in FIG. 8. FIG. 8 is a diagram for explaining the evaluation results of the implementation methods shown in FIG. 7. The comparative example is a system that implements an inverse filter matrix and is a related art system that adopts the principle of optimal sound source distribution. The evaluation is a relative evaluation, and the ranks are determined as A, B, and C in descending order of evaluation. The evaluation items were “Simplicity of theory,” “Accuracy of inverse system,” “Lowness of circuit implementation cost,” and “Simplicity of inverse system design.”

For “Simplicity of theory,” the comparative example was evaluated as “A,” and the first to fourth implementation methods M1 to M4 were evaluated as “B.” The first to fourth implementation methods M1 to M4 were evaluated as more complex than the comparative example because they partition the formula of the comparative example into elements.

### [Accuracy of Inverse System]

In the comparative example, theoretically, the product of the plant matrix and the inverse filter matrix becomes an identity matrix, so the comparative example was evaluated as “A.” In contrast, the first to fourth implementation methods M1 to M4 were evaluated as “B” or lower because they approximate the elements of the inverse filter matrix. Among the first to fourth implementation methods M1 to M4, the first implementation method M1 has the most items to be approximated, so only the first implementation method M1 was evaluated as “C,” and the second to fourth implementation methods M2 to M4 were evaluated as “B.”

### [Lowness of Circuit Implementation Cost]

The comparative example requires a convolution circuit, so it was evaluated lower than the first to fourth implementation methods M1 to M4. The third and fourth implementation methods M3 and M4 have relatively complex feedback circuits, so they were evaluated lower than the first and second implementation methods M1 and M2. Based on the above, the comparative example was evaluated as “C,” the first and second implementation methods M1 and M2 were evaluated as “A,” and the third and fourth implementation methods M3 and M4 were evaluated as “B.”

### [Simplicity of Inverse System Design]

The comparative example requires designing the inverse filter matrix for each frequency, so it was evaluated lower than the first to fourth implementation methods M1 to M4. The third and fourth implementation methods M3 and M4 require setting the stabilization parameter of the feedback circuit, so they were evaluated lower than the first and second implementation methods M1 and M2. Based on the above, the comparative example was evaluated as “C,” the first and second implementation methods M1 and M2 were evaluated as “A,” and the third and fourth implementation methods M3 and M4 were evaluated as “B.”

### Summary of Embodiment

According to the sound reproduction system 1, the inverse filter matrix Hᵢ is approximated by an approximate inverse matrix. The approximate inverse matrix is applied to the left recording signal 41 and the right recording signal 42, whereby the multi-way speaker unit 2 reproduces sound. The approximate inverse matrix is expressed as a product of the gain correction term αᵢ, the coefficient correction term Gᵢ, the phase inversion term Rᵢ, and the delay correction term Dᵢ. In other words, the inverse filter matrix, which performs convolution operations with long filter coefficients, is approximately divided into four elements that perform simpler operations such as gain correction, coefficient correction, phase inversion, and delay correction. The functions related to the four elements are implemented by being shared among a plurality of circuits. Therefore, the sound reproduction system 1 can reduce the implementation cost related to independent control of both ears compared to a case where the inverse filter matrix is implemented as is.

### [Modification]

Although various exemplary embodiments have been described above, the present disclosure is not limited to the above-described exemplary embodiments, and various omissions, substitutions, and changes may be made.

The number of right speakers and the number of left speakers described in the above-described embodiments may be changed as appropriate. The number of right speakers and the number of left speakers do not have to be the same.

### EXAMPLE

Hereinafter, an example conducted by the present inventors to explain the above effects will be described.

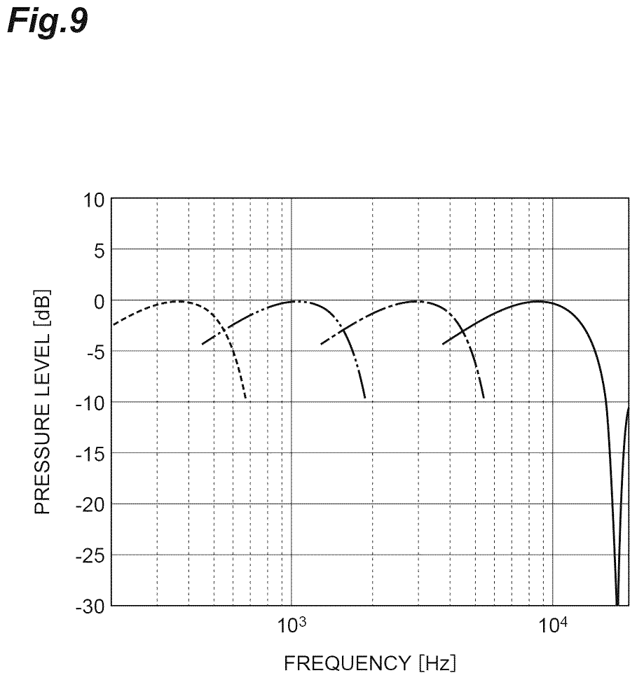

The sound reproduction system 1 shown in FIG. 1 was used. The inverse filter matrix was implemented by the second implementation method M2. The frequency band was divided into four parts. Then, sound was output to only one ear, and the frequency response at the other ear (control point) was simulated. The results are shown in FIG. 9. FIG. 9 is a graph simulating the frequency response at the control point. The horizontal axis is frequency [Hz], and the vertical axis is sound pressure level [dB]. In the second implementation method M2, crosstalk is completely canceled in terms of numerical calculation. When the recording signal can be accurately reproduced at the control point, the vertical axis is 0 dB. As shown in FIG. 9, it was confirmed that although there are variations in the sound pressure level depending on the frequency, it is generally within −5 dB.

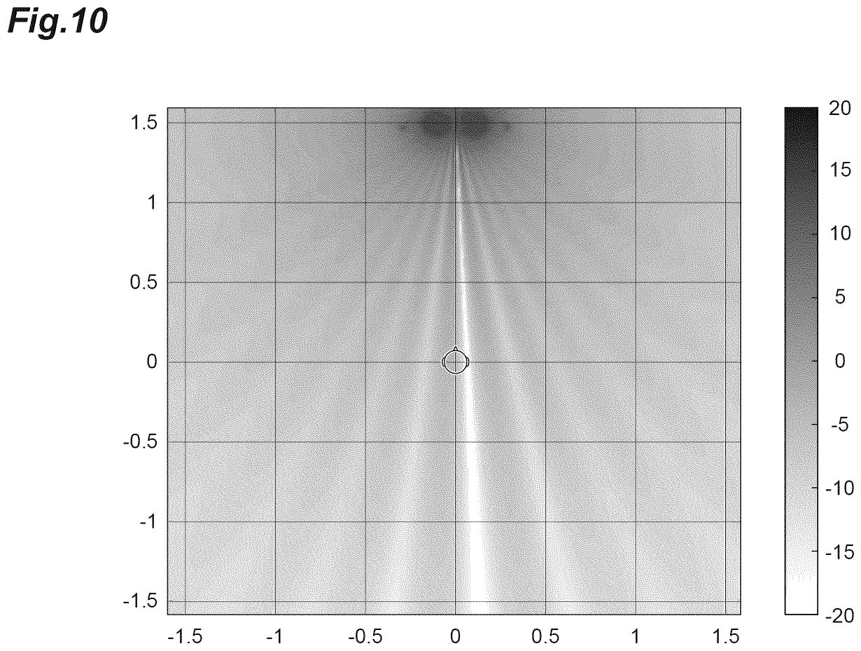

The sound pressure distribution was simulated assuming that the listener 11 is located at the origin in the above-described listening space 10. The sound reproduction system 1 was the same as the system used in the evaluation of FIG. 9. The results are shown in FIG. 10. FIG. 10 is a result of simulating the sound pressure distribution by a sound reproduction system realized by an approximate inverse matrix. FIG. 10 is a diagram expressing the sound pressure level [dB] by shading. As shown in FIG. 10, it was confirmed that the left ear of the listener (at the origin position) is approximately 0 dB, and the right ear is about −20 dB, that is, the sound is sufficiently attenuated at the right ear. Thus, it was confirmed that independent control of both ears can be realized using an approximate inverse matrix.

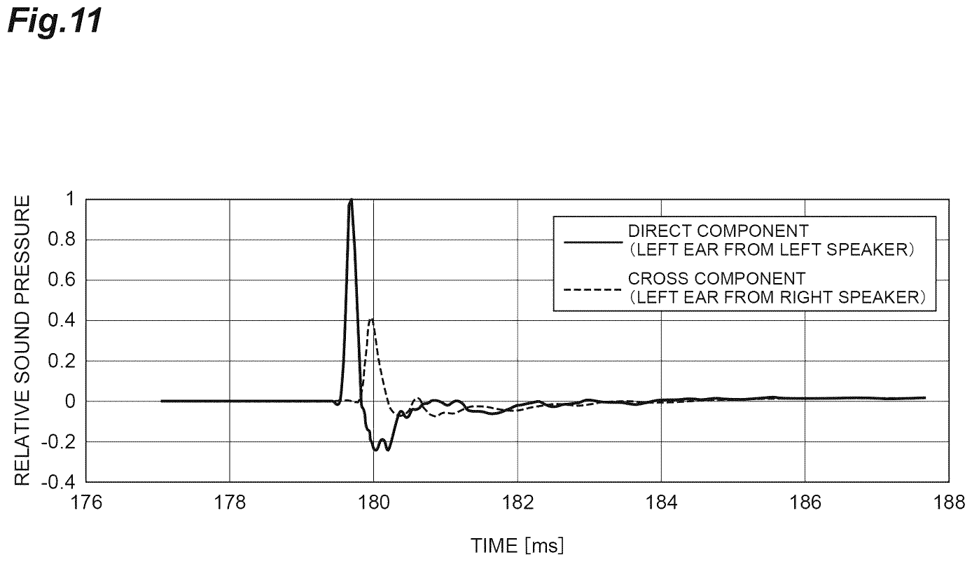

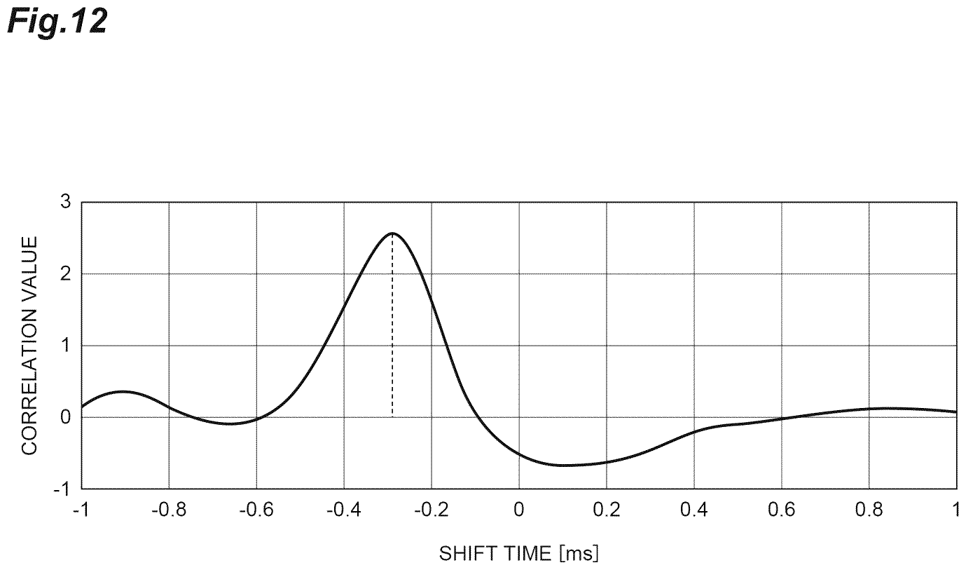

Next, an example of parameter setting will be described. A calculation example of parameters when a pair of left and right speakers are arranged at a position where the opening angle θ of the speakers is 29 deg. is shown. First, the delay time Δtᵢ is calculated. FIG. 11 is a result of simulating the impulse response of sound arriving at the left ear from a pair of left and right speakers. The horizontal axis is time [ms], and the vertical axis is relative sound pressure. The relative sound pressure is the sound pressure normalized so that the peak value of the impulse response of the direct component arriving at the left ear from the left speaker (head-related impulse response considering the head) is 1. The solid line data shown in FIG. 11 is the impulse response of the direct component arriving at the left ear from the left speaker, and the one-dot chain line data is the impulse response of the cross component arriving at the left ear from the right speaker. A time difference (shift time) was given to the impulse response of the direct component and the impulse response of the cross component, and a cross-correlation function that returns the magnitude of the overlap of the impulse responses at the given time difference as a correlation value was prepared and calculated. FIG. 12 is a calculation result of a cross-correlation function between the impulse response of the direct component and the impulse response of the cross component. The horizontal axis is the shift time, and the vertical axis is the correlation value. As shown in FIG. 12, the shift time at which the correlation value is maximized was −0.29 ms. That is, it indicates that the direct component arrived 0.29 ms earlier than the cross component. Therefore, in the frequency band assigned to the pair of left and right speakers, the delay time Δtᵢ should be 0.29 ms.

Next, the transfer gain ratio gᵢ is calculated. When calculating the transfer gain ratio gᵢ by the effective value, the square root is taken of the value obtained by dividing the integral of the square of the head-related impulse response shown in FIG. 11 by the integration time length, and the resulting value is set as the transfer gain of each of the direct component and the cross component (see formula (26)). Then, the ratio of the transfer gains of the direct component and the cross component is calculated. As a result, the transfer gain ratio gᵢ becomes 2.04.

When calculating the transfer gain ratio gᵢ by the maximum energy value, the ratio of the maximum value among the absolute values at each time of the impulse response of the direct component shown in FIG. 11 to the maximum value among the absolute values at each time of the impulse response of the cross component is calculated. As a result, the transfer gain ratio gᵢ becomes 2.44. As described above, it was confirmed that the parameters can be calculated clearly and simply.

### REFERENCE SIGNS LIST

1 . . . sound reproduction system, 2 . . . multi-way speaker unit (an example of a plurality of speakers), 3 . . . controller, 10 . . . listening space, 11 . . . listener, 41 . . . left recording signal, 42 . . . right recording signal, LW . . . plurality of left speakers, RW . . . plurality of right speakers.

1. A sound reproduction system for reproducing sound in a listening space in which a listener is present, comprising:
a plurality of speakers disposed in the listening space; and
a controller configured to cause the plurality of speakers to reproduce two channels of sound including a left channel and a right channel, based on a left recording signal corresponding to a left ear of the listener and a right recording signal corresponding to a right ear of the listener;
wherein the plurality of speakers comprises a plurality of left speakers corresponding to the left channel and a plurality of right speakers corresponding to the right channel, and a discretized frequency bandwidth is preset for each of the plurality of left speakers and for each of the plurality of right speakers such that their respective output frequency bandwidths differ;
the controller configured to apply an approximate inverse matrix, which approximates an inverse of a plant matrix representing transfer paths from the plurality of speakers to both ears of the listener, to the left recording signal and the right recording signal, thereby causing the plurality of speakers to reproduce sound;
the sound output from the plurality of speakers comprises direct components being sound output from the plurality of left speakers to the listener's left ear and from the plurality of right speakers to the listener's right ear and cross components being sound output from the plurality of left speakers to the listener's right ear and from the plurality of right speakers to the listener's left ear;
the approximate inverse matrix is expressed as a product of a gain correction term that corrects the signal intensity of the direct components in a frequency-dependent manner, a coefficient correction term that corrects, in a frequency-dependent manner, the intensity difference between the direct components and the cross components, a phase inversion term that inverts the phase of the cross components, and a delay correction term that applies a frequency-dependent time delay to the cross components; and
the controller comprises a plurality of circuits implementing the gain correction term, the coefficient correction term, the phase inversion term, and the delay correction term.

2. The sound reproduction system according to claim 1, wherein the controller comprises an amplification circuit implementing the gain correction term and the coefficient correction term, and a delay circuit implementing the phase inversion term and the delay correction term; and
the delay circuit provides, uniformly within each discretized frequency band, a sum of: a time difference such that a phase difference between the direct components and the cross components is 180 degrees at a center frequency of the frequency bandwidth; and an arrival time difference between the direct components and the cross components.

3. The sound reproduction system according to claim 1, wherein the controller comprises an amplification circuit implementing the gain correction term and the coefficient correction term, an inversion circuit implementing the phase inversion term, and a delay circuit implementing the delay correction term;
the inversion circuit inverts the signal polarity; and
the delay circuit provides, uniformly within each discretized frequency band, an arrival time difference between the direct components and the cross components.

4. The sound reproduction system according to claim 1, wherein the controller comprises a feedback circuit implementing the gain correction term, an amplification circuit implementing the coefficient correction term, and a delay circuit implementing the phase inversion term and the delay correction term;
the feedback circuit calculates the gain correction term as a function of frequency; and
the delay circuit provides, uniformly within each discretized frequency band, a sum of: a time difference such that a phase difference between the direct components and the cross components is 180 degrees at a center frequency of the frequency bandwidth; and an arrival time difference between the direct components and the cross components.

5. The sound reproduction system according to claim 1, wherein the controller comprises a feedback circuit implementing the gain correction term, an amplification circuit implementing the coefficient correction term, an inversion circuit implementing the phase inversion term, and a delay circuit implementing the delay correction term;
the feedback circuit calculates the gain correction term as a function of frequency;
the inversion circuit inverts the signal polarity; and
the delay circuit provides, uniformly within each discretized frequency band, an arrival time difference between the direct components and the cross components.

6. The sound reproduction system according to claim 2, wherein the arrival time difference is a time difference at which a correlation between an impulse response of the direct components and an impulse response of the cross components is maximized.

7. The sound reproduction system according to claim 2, wherein the gain correction term is a value within a range from 0.1 to 10.

8. The sound reproduction system according to claim 2, wherein the gain correction term is γ/(1+gi2), where γ is a value within a range from 0.1 to 10, and gi is a transfer gain ratio representing a ratio of signal intensities resulting from a path difference between the direct components and the cross components of a speaker in an i-th frequency band.

9. The sound reproduction system according to claim 8, wherein the transfer gain ratio is a ratio of a square root of a time-averaged integral of squared values of an impulse response of the direct components to a square root of a time-averaged integral of squared values of an impulse response of the cross components.

10. The sound reproduction system according to claim 8, wherein the transfer gain ratio is a ratio of a maximum absolute value of an impulse response of the direct components to a maximum absolute value of an impulse response of the cross components.

11. The sound reproduction system according to claim 4, wherein the gain correction term and the coefficient correction term are associated with a transfer gain ratio gi, which is a ratio of signal intensities resulting from a path difference between the direct components and the cross components of a speaker in an i-th frequency band.

12. The sound reproduction system according to claim 11, wherein the transfer gain ratio is a ratio of a square root of a time-averaged integral of squared values of an impulse response of the direct components to a square root of a time-averaged integral of squared values of an impulse response of the cross components.

13. The sound reproduction system according to claim 11, wherein the transfer gain ratio is a ratio of a maximum absolute value of an impulse response of the direct components to a maximum absolute value of an impulse response of the cross components.
